(19) United States
(12) Patent Application Publication
(10) Pub. No.: US 2015/0188017 A1
(43) Pub. Date: Jul. 2, 2015

(54) GRAPHENE THIN FILM WITH FOLDED CONFIGURATION, THERMOELECTRIC DEVICE INCLUDING GRAPHENE THIN FILM AND FABRICATION METHOD THEREOF

(71) Applicant: Industrial Technology Research Institute, Hsinchu (TW)

(72) Inventors: Kuang-Yao Chen, Hualien County (TW); Meng-Chang Lin, Taichung City (TW); Shin-Pon Ju, Kaohsiung City (TW); Ya-Ping Hsieh, Kaohsiung City (TW)

(73) Assignee: Industrial Technology Research Institute, Hsinchu (TW)

(21) Appl. No.: 14/271,460

(22) Filed: May 7, 2014

(30) Foreign Application Priority Data
Dec. 27, 2013 (TW) 102148793

(51) Int. Cl. H01L 35/28; C01B 31/04; B29C 53/04

(52) U.S. Cl. CPC H01L 35/28; B29C 53/04; C01B 31/0453

(57) ABSTRACT

A graphene thin film with folded configuration including a plurality of sheet layers is provided. Any two adjacent sheet layers are separated by a distance. Each of the sheet layers has a first side and a second side corresponding to the first side. At least one first connecting portion and at least one second connecting portion are alternately arranged on both sides of the sheet layers. One of the at least one first connecting portions connects the first side of an N^{th} sheet layer and the first side of the (N−1)^{th} sheet layer, and one of the at least one second connecting portions connects the second side of the N^{th} sheet layer and the second side of the (N+1)^{th} sheet layer. The sheet layers, the at least one first connecting portion, and the at least one second connecting portion form a continuous graphene thin film.

### CROSS-REFERENCE TO RELATED APPLICATION

This application claims the priority benefit of Taiwan application serial no. 102148793, filed on Dec. 27, 2013. The entirety of the above-mentioned patent application is hereby incorporated by reference herein and made a part of this specification.

### TECHNICAL FIELD

The disclosure is related to a graphene thin film with folded configuration, a thermoelectric device including the graphene thin film, and a fabrication method thereof.

### BACKGROUND

The development of renewable energy technology has gained increasing attention in recent years due to energy shortage. In the field of power generation through thermoelectric conversion, the conversion between thermal energy and electrical energy is generally performed by driving electrons move with the temperature difference between a thermoelectric material and a device. In addition, power generation by thermoelectric conversion can further be combined with the technology of recycling waste heat, in which the waste heat is used as a heat source for power generation through thermoelectric conversion, so as to reduce waste of energy. As a result, the environmental benefits of reduced heat dissipation and energy renewal can be achieved.

However, the largest issue in the application of power generation through thermoelectric conversion is that the efficiency of the thermoelectric conversion is limited. The energy conversion efficiency of the known thermoelectric material and the figure of merit (ZT) are in a close relation, which can be represented by an equation: ZT=S²σT/κ. In particular, S is the Seebeck coefficient, σ is electrical conductivity, and κ is the thermal conductivity. The efficiency of a theimoelectric cooling device and a thermoelectric generator is better when the figure of merit is higher. Therefore, it can be seen from the formula that, a good thermoelectric material needs to have a good Seebeck coefficient, a high electrical conductivity, and a low thermal conductivity.

A material having a high electrical conductivity generally has good thermal conduction, and a material having a low thermal conductivity is generally an insulator. It can therefore be known that, electrical conductivity and thermal conductivity are related, and that it is difficult for a common material to have a good electrical conductivity and a low thermal conductivity at the same time. As a result, the final figure of merit can not be effectively increased. Based on the above, how to maintain the electrical conductivity of a material and effectively reduce the thermal conductivity thereof under a specific condition is a desired current research.

### SUMMARY

The disclosure provides a graphene thin film with folded configuration including a plurality of sheet layers, at least one first connecting portion, and at least one second connecting portion. In particular, any two adjacent sheet layers are separated by a distance, each of the sheet layers has a first side and a second side, and the first side and the second side correspond to each other. The at least one first connecting portion and the at least one second connecting portion are alternately arranged on both sides of each of the sheet layers. In particular, the N^{th} layer is any one of the sheet layers, one of the at least one first connecting portions connects the first side of the N^{th} sheet layer and the first side of the (N−1)^{th} sheet layer, and one of the at least one second connecting portions connects the second side of the N^{th} sheet layer and the second side of the (N+1)^{th} sheet layer. The sheet layers, the at least one first connecting portion, and the at least one second connecting portion form a continuous graphene thin film.

The disclosure provides a thermoelectric device including a lower substrate, a lower electrode located on the lower substrate, a graphene thin film with folded configuration located on the lower electrode, an upper electrode located above the graphene thin film with folded configuration, and an upper substrate located on the upper electrode. The graphene thin film with folded configuration includes a plurality of sheet layers, at least one first connecting portion, and at least one second connecting portion. Any two adjacent sheet layers are separated by a distance, each of the sheet layers has a first side and a second side, and the first side and the second side correspond to each other, wherein the sheet layers and the surface of the lower substrate are parallel. The at least one first connecting portion and the at least one second connecting portion are alternately arranged on both sides of each of the sheet layers. In particular, one of the at least one first connecting portions connects the first side of an N^{th} sheet layer and the first side of an (N−1)^{th} sheet layer, and one of the at least one second connecting portions connects the second side of the N^{th} sheet layer and the second side of an (N+1)^{th} sheet layer, wherein the N^{th} sheet layer is any one of the sheet layers. In particular, the sheet layers, the at least one first connecting portion, and the at least one second connecting portion form a continuous graphene thin film.

The disclosure provides a fabrication method of a graphene thin film with folded configuration including providing a substrate, forming a graphene layer on the substrate, and forming a protective layer on the graphene layer. The substrate is folded multiple times to form a plurality of connecting portions and a plurality of sheet layers. The substrate and the protective layer are removed to form a graphene layer with folded configuration.

In the following, specific embodiments are used to describe the implementation of the disclosure. Those skilled in the art can conceive other advantages and efficacy of the disclosure from the contents disclosed in the present specification. The disclosure can also be implemented or applied through other different specific embodiments, and the details of the present specification can also be modified and changed based on different views and applications without departing from the spirit of the disclosure.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram of a graphene thin film with folded configuration according to an embodiment of the disclosure.

FIG. 2A is an enlarged side view of region B in FIG. 1 according to an embodiment of the disclosure.

FIG. 2B is an enlarged side view of region B in FIG. 1 according to another embodiment of the disclosure.

FIG. 3 is a flow chart of a fabrication method of a graphene thin film with folded configuration according to an embodiment of the disclosure.

FIG. 4A to FIG. 4C are cross-sectional diagrams of a fabrication method of a graphene thin film with folded configuration according to an embodiment of the disclosure.

FIG. 5 is a schematic diagram of a thermoelectric device according to an embodiment of the disclosure.

FIG. 6A is a schematic diagram of four probe sheet resistance measurement of a graphene thin film with folded configuration according to embodiment 3 of the disclosure.

FIG. 6B is a schematic diagram of four probe sheet resistance measurement of a monolayer graphene thin film without folded configuration according to comparative embodiment 1.

FIG. 7A is a schematic diagram of voltage versus current of a graphene thin film with folded configuration and the straight line fit according to embodiment 3 of the disclosure.

FIG. 7B is a schematic diagram of voltage versus current of a monolayer graphene thin film without folded configuration and the straight line fit according to comparative embodiment 1.

### DETAILED DESCRIPTION OF DISCLOSED EMBODIMENTS

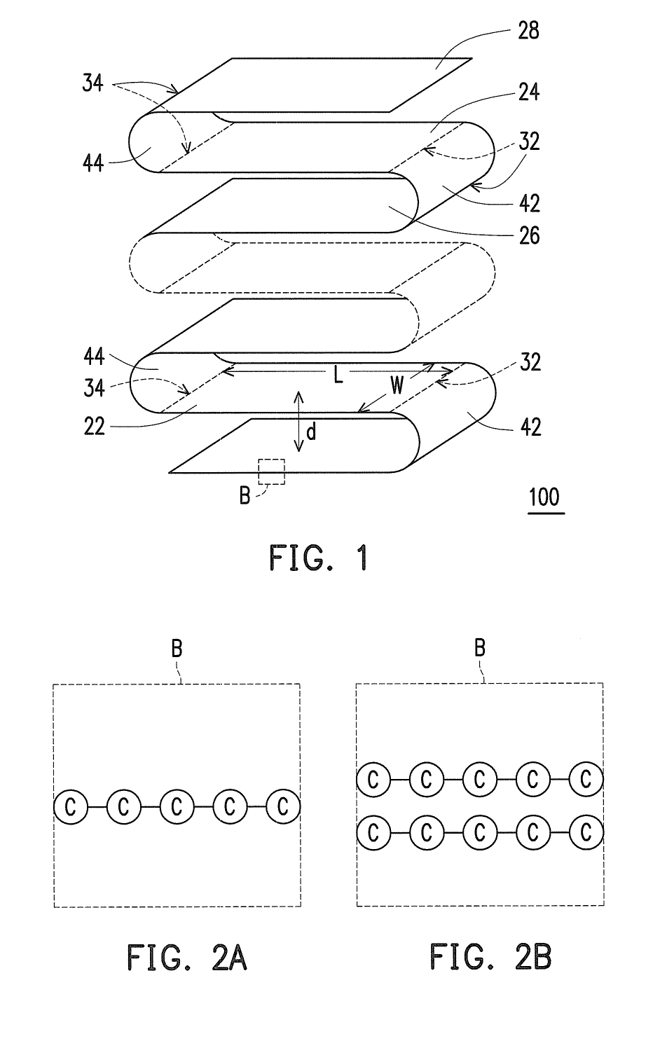

FIG. 1 is a schematic diagram of a graphene thin film with folded configuration according to an embodiment of the disclosure.

Referring to FIG. 1, a graphene thin film 100 with folded configuration includes a plurality of sheet layers 22, at least one first connecting portion 42, and at least one second connecting portion 44. The plurality of sheet layers 22, the at least one first connecting portion 42, and the at least one second connecting portion 44 form a continuous graphene thin film 100.

As shown in FIG. 1, each of the sheet layers 22 is, for instance, a flat surface. Each of the sheet layers 22 has a first side 32 and a second side 34, and the first side 32 and the second side 34 correspond to each other. In an embodiment, the first side 32 and the second side 34 are parallel to each other. The shape of each of the plurality of sheet layers 22 can be the same or different, and the shape can be, for instance, quadrilateral or polygonal. In an embodiment, each of the sheet layers 22 is rectangular, and a length L thereof is, for instance, 5 nanometers to 10 meters, a width W thereof is, for instance, 5 nanometers to 10 meters, and the thickness thereof is, for instance, 0.1 angstroms to 3 nanometers.

The plurality of sheet layers 22 can be parallel or not parallel to one another. In an embodiment, the graphene thin film 100 includes a plurality of sheet layers 22 parallel to one another. In another embodiment, the graphene thin film 100 can include at least one group of sheet layers 22 parallel to one another and at least one group of sheet layers 22 not parallel to one another at the same time. Any two adjacent sheet layers 22 are separated by a distance d. Each of the distances d can be the same or different. In an embodiment, the size of the distance d is, for instance, between 0.3 nanometers and 10 nanometers.

The at least one first connecting portion 42 and the at least one second connecting portion 44 are alternately arranged on both sides of each of the sheet layers 22. In FIG. 1, the at least one first connecting portion 42 is disposed on the right side and the at least one second connecting portion 44 is disposed on the left side. The shape of each of the at least one first connecting portion 42 and the at least one second connecting portion 44 can be, for instance, an arc, a curve, a paraboloid, a cusp, or a vertical plane. The shape of each of the at least one first connecting portion 42 and the at least one second connecting portion 44 can be the same or different. In an embodiment, each of the at least one first connecting portion 42 and the at least one second connecting portion 44 can be an arc having the same or different curvatures.

Referring to FIG. 1, the graphene thin film 100 with folded configuration of the disclosure includes the plurality of sheet layers 22, the at least one first connecting portion 42, and the at least one second connecting portion 44. More specifically, the plurality of sheet layers 22 can include sheet layers 24, 26, and 28. The N^{th} sheet layer 24 is any one of the plurality of sheet layers 22, but is not the bottommost sheet layer 22 or the topmost sheet layer 22. One of the at least one first connecting portions 42 connects the first side 32 of the N^{th} sheet layer 24 and the first side 32 of the (N−1)^{th} sheet layer 26, and one of the at least one second connecting portions 44 connects the second side 34 of the N^{th} sheet layer 24 and the second side 34 of the (N+1)^{th} sheet layer 28. The plurality of sheet layers 22, the at least one first connecting portion 42, and the at least one second connecting portion 44 form a continuous graphene thin film 100 with folded configuration.

The graphene thin film 100 with folded configuration shown in FIG. 1 is only exemplary, and is not intended to limit the disclosure. That is, the plurality of sheet layers 22, the at least one first connecting portion 42, and the at least one second connecting portion 44 below the dotted portion in FIG. 1 can be omitted. Alternatively, the dotted portion in FIG. 1 can include the plurality of sheet layers 22, the at least one first connecting portion 42, and the at least one second connecting portion 44. The number of layers of the plurality of sheet layers 22 of the disclosure can be, for instance, 2 to 400 layers.

FIG. 2A is an enlarged side view of region B in FIG. 1 according to an embodiment of the disclosure. FIG. 2B is an enlarged side view of region B in FIG. 1 according to another embodiment of the disclosure.

Referring to FIG. 2A and FIG. 2B, in an embodiment of the disclosure, the plurality of sheet layers 22, the at least one first connecting portion 42, and the at least one second connecting portion 44 of the graphene thin film 100 respectively include a graphene of a monolayer of carbon atoms as shown in FIG. 2A. In another embodiment of the disclosure, each of the plurality of sheet layers 22, each of the at least one first connecting portion 42, and each of the at least one second connecting portion 44 of the graphene thin film 100 respectively include a graphene of multiple layers (such as 2 layers to 20 layers) of carbon atoms as shown in FIG. 2B. In particular, the thickness of each of the layers of carbon atoms ranges from, for instance, 0.1 angstroms to 3 nanometers.

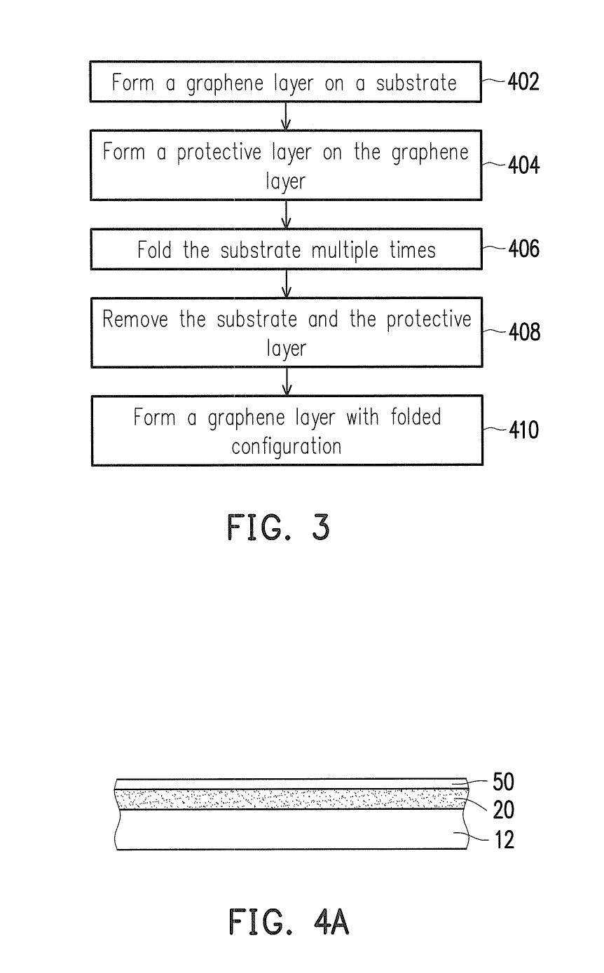

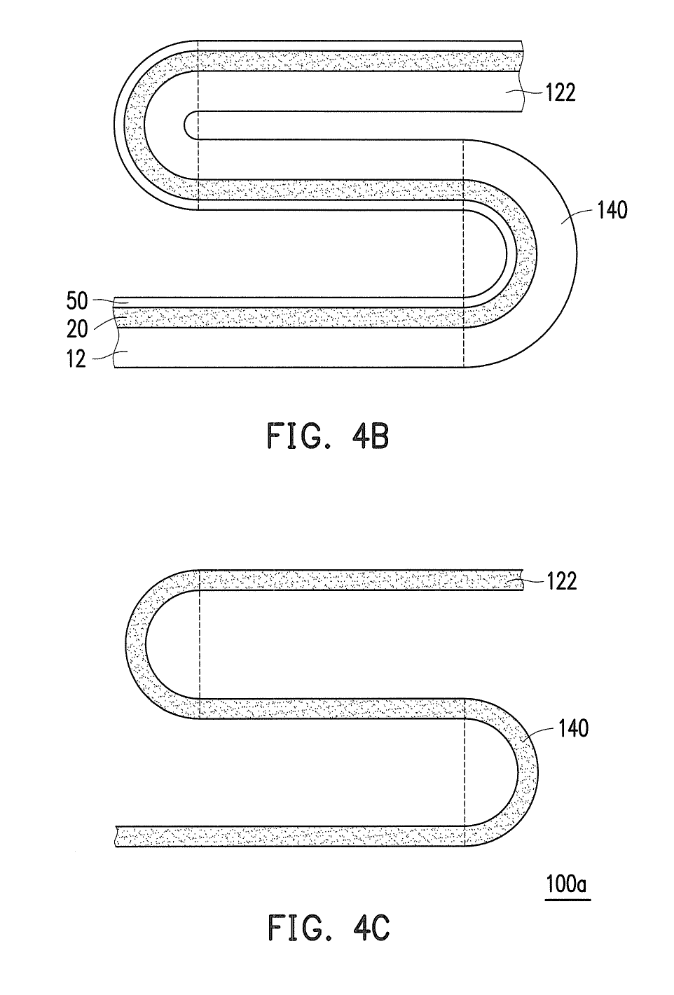

FIG. 3 is a flow chart of a fabrication method of a graphene thin film with folded configuration according to an embodiment of the disclosure. FIG. 4A to FIG. 4C are cross-sectional diagrams of a fabrication method of a graphene thin film with folded configuration according to an embodiment of the disclosure.

Referring to FIG. 3 and FIG. 4A, in step 402, a graphene layer 20 is formed on a substrate 12. The substrate 12 includes a flexible substrate, and can be used as a metal catalyst. The material of the substrate 12 includes any material capable of growing graphene. In an embodiment, the substrate 12 is, for instance, copper foil. The forming method of the graphene layer 20 includes a vapor deposition method or a mechanical stripping method. The vapor deposition method is, for instance, a chemical vapor deposition (CVD) method. In an embodiment of the disclosure, the step of using a CVD method to form the graphene layer 20 includes heating, annealing, growing graphene, and cooling. For instance, with copper foil as the substrate 12, in the present embodiment, copper foil is used as a metal catalyst to grow a uniform monolayer graphene having a large area. The growth step can be performed in, for instance, a reaction environment with a vacuum pressure lower than 10⁻² torr. The first stage is heating, wherein the temperature is raised to, for instance, 1000° C., and the heating rate is determined by the specifications of the high temperature furnace used. Then, the second stage (annealing) is performed. A vacancy is moved in the copper lattice and internal residual stress is released by annealing. The phenomenon of reduced dislocation of lattice arrangement is achieved through atom rearrangement. As a result, the generation of a defect is reduced. The first two stages are both preparations for the growth of graphene, wherein a gas such as hydrogen gas is introduced at the same time to remove organic matter and copper oxide from the surface of the copper foil. The third stage is the growth of graphene. In this stage, a carbon source such as methane is introduced and the flow rate of the hydrogen gas is increased. In this stage, the role of the hydrogen gas is to suppress the growth of graphene and to carry away the excess carbon atoms on the surface of the copper foil. Moreover, the density of the carbon atoms is reduced after introducing the hydrogen gas, such that the growth reaction of graphene can proceed slowly. As a result, the generation of an alignment defect of the carbon atoms can be reduced. In an embodiment, multiple graphene layers 20 can also be grown to have a large area. Then, the last stage (cooling) is performed. Due to the recrystallization of copper atoms, in the cooling process, a grain boundary is generated at the locations of lattice dislocation due to internal stress. Moreover, due to different coefficients of expansion, a wrinkle is generated at the graphene adjacent to the grain boundary, and therefore the graphene needs to be slowly cooled to, for instance, 800° C. A temperature lower than, for instance, 900° C., is close to the limit of graphene growth, and at this point the introduction of methane is stopped and the flow rate of the hydrogen gas is adjusted back to the initial trace amount. When the temperature is lower than, for instance, 100° C., the growth of graphene can be stopped to complete the reaction. In another embodiment of the disclosure, the forming method of the graphene layer 20 further includes performing a doping treatment to the graphene layer 20. The method of the doping treatment includes, for instance, a plasma method, a heat treatment method, or a solution method. Moreover, the method of the doping treatment includes implanting nitrogen atoms, hydrogen atoms, oxygen atoms, ammonium atoms, or a combination thereof. In an embodiment, an oxygen plasma treatment can be performed on the graphene layer 20. In this way, the thermoelectric power factor (S²σ) of the graphene layer 20 can be increased so as to increase the figure of merit (ZT), thereby increasing thermoelectric performance. It should be understood that, the graphene thin film 100 with folded configuration of the disclosure can include a graphene layer 20 that has been subject to a doping treatment. In other words, by applying a folded configuration to the graphene layer 20 having high thermoelectric power factor, the thermoelectric performance can be further increased.

Referring further to FIG. 3 and FIG. 4A, in step 404, after the graphene layer 20 is formed on the substrate 12, a protective layer 50 is formed on the graphene layer 20. The material of the protective layer 50 is, for instance, poly methyl methacrylate (PMMA). The forming method of the protective layer 50 is, for instance, a spin coating method. The thickness of the protective layer 50 is, for instance, 10 nanometers to 2 millimeters. After the PMMA is coated on the graphene layer 20, the graphene layer 20 is heated to solidify the PMMA. For instance, the graphene layer 20 is heated at 70° C. for 5 minutes to form the protective layer 50.

Referring to FIG. 3 and FIG. 4B, in step 406, the substrate 12 containing the graphene layer 20 and the protective layer 50 is folded at least once or multiple times to form a plurality of connecting portions 140 and a plurality of sheet layers 122. In particular, the sheet layers 122 can include 2 to 400 layers. The folding method includes a folding and stacking method. The shape of each of the plurality of connecting portions 140 can be, for instance, an arc, a curve, a paraboloid, a cusp, or a vertical plane. The shape of each of the plurality of connecting portions 140 can be the same or different. In an embodiment, each of the plurality of connecting portions 140 can be an arc with the same or different curvatures. Moreover, the length of each of the sheet layers 122 can be the same or different, and each of the sheet layers 122 can be parallel or not parallel to one another. In yet another embodiment, each of the sheet layers 122 is parallel to one another. In another embodiment of the disclosure, each of the sheet layers 122 and each of the connecting portions 140 respectively include a graphene of a monolayer of carbon atoms or of multiple layers of carbon atoms.

Referring to FIG. 3 and FIG. 4C, in step 408, the substrate 12 and the protective layer 50 are removed. The removal method of the substrate 12 includes a wet etching method, and the etching solution can contain ferric chloride (FeCl₃). In an embodiment, copper foil is exemplarily used as the substrate 12, and in addition to the ferric chloride etching solution contained in the solution, it can be known from the following reaction formulas that, copper is etched by ferric chloride to generate cuprous chloride (CuCl), and cuprous chloride is reacted with ferric chloride to form copper chloride (CuCl₂). Copper chloride itself can also be used to perform etching on the copper foil. Therefore, during the process of etching with ferric chloride, two etching reactions are performed at the same time, and a significant etching effect is achieved.

FeCl₃+Cu→FeCl₂+CuCl formula (1)

FeCl₃+CuCl→FeCl₂+CuCl₂ formula (2)

CuCl₂+Cu→2CuCl formula (3)

The removal method of the protective layer 50 includes immersing the protective layer 50 and the graphene layer 20 into a solvent for dissolving the protective layer 50 after the substrate 12 is removed. In an embodiment of the disclosure, and in an exemplary embodiment in which polymethyl methacrylate (PMMA) is used as the protective layer 50, the protective layer 50 and the graphene layer 20 can be immersed in acetone for 30 to 50 minutes to remove the protective layer 50. Then, the acetone stuck on the surface of the graphene layer 20 is removed with isopropanol to form a graphene layer 100a with folded configuration as shown in step 410.

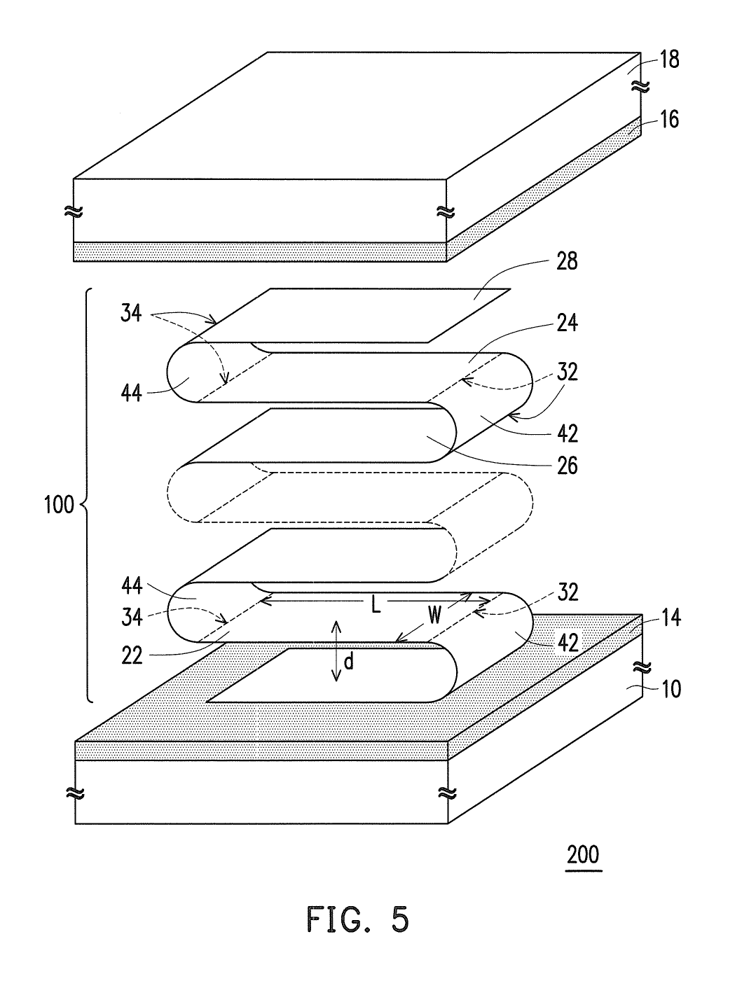

FIG. 5 is a schematic diagram of a thermoelectric device according to an embodiment of the disclosure. The graphene thin film 100 with folded configuration of the disclosure can be applied in a thermoelectric device. Referring to FIG. 5, a thermoelectric device 200 includes a lower substrate 10, a lower electrode 14, the graphene thin film 100 with folded configuration, an upper electrode 16, and an upper substrate 18. The lower substrate 10 includes a rigid substrate or a flexible substrate. The rigid substrate is, for instance, a glass substrate, a ceramic substrate, or an aluminum nitride or silicon carbide substrate. The flexible substrate is, for instance, a plastic substrate, a polyimide substrate, or a metal oxide or metal nitride thin film flexible substrate. The lower substrate 10 can include a semiconductor material, an insulating material, or a combination of the materials. The lower electrode 14 is located on the lower substrate 10, and the material of the lower electrode 14 can include a conductive material such as copper, silver, graphite, graphene, or indium tin oxide. The forming method of the lower electrode 14 is not particularly limited, and can be suitably selected according to the electrode material. Specifically, the forming method of the lower electrode 14 includes, for instance, coating and printing, low-temperature co-firing, or coating. The graphene thin film 100 with folded configuration includes a plurality of sheet layers 22, at least one first connecting portion 42, and at least one second connecting portion 44. In an embodiment, the plurality of sheet layers 22 and the surface of the lower substrate 10 are parallel. The plurality of sheet layers 22, the at least one first connecting portion 42, and the at least one second connecting portion 44 form a continuous graphene thin film 100. The graphene thin film 100 with folded configuration is as shown in FIG. 1 and is not repeated herein. The upper electrode 16 is located above the graphene thin film 100 with folded configuration and can be in contact with the graphene thin film 100 with folded configuration. For drawing clarity, in FIG. 5, the upper electrode 16 is illustrated to be above the graphene thin film 100 with folded configuration and is not in contact with the graphene thin film 100 with folded configuration. The upper substrate 18 is located on the upper electrode 16, and the material of the upper substrate 18 is the same as the material of the lower substrate 10 and is not repeated herein.

Referring to FIG. 5, when the thermoelectric device 200 including the graphene thin film 100 with folded configuration is in operation, electrons can be transferred through carbon atoms in each of the sheet layers 22. In other words, the direction of electron transfer of the thermoelectric device 200 is an in-plane direction, that is, the direction parallel to the sheet layers 22. Since the direction of electron transfer is an in-plane direction, the original electrical conductivity σ of the graphene material can be maintained. However, the direction of thermal conduction of the thermoelectric device 200 is a cross-plane direction, that is, the orthogonal direction of each of the sheet layers 22. A weak carbon-carbon bond between the sheet layers 22 in the cross-plane direction and the folded configuration of the graphene thin film 100 cause the thermal conductivity κ of the graphene thin film 100 to be reduced. In other words, when the thermal conductivity κ is reduced, the electrical conductivity σ of the thermoelectric device 200 is not reduced as a result. That is, the thermoelectric device 200 of the disclosure including the graphene thin film 100 with folded configuration can have the characteristics of a high electrical conductivity and a low thermal conductivity at the same time, and is therefore a high efficiency thin film thermoelectric device.

In another embodiment of the disclosure, since the graphene material itself has high light transmittance, the thermoelectric device 200 with the characteristics of a high electrical conductivity and a low thermal conductivity at the same time can be applied to a glass. Moreover, the thermoelectric device 200 can perform recycling of power generation through thermoelectric conversion via the temperature difference between the hot and cold ends of the glass under the condition that illumination is not affected. In yet another embodiment, when current is provided to the thermoelectric device 200, fogging on the glass can be prevented through a cooling-heating effect of the thermoelectric device 200. Moreover, in still yet another embodiment of the disclosure, a compact thermoelectric device 200 including the graphene thin film 100 with folded configuration can be formed. The thermoelectric device 200 can be attached to, for instance, a heat source device to perform power generation through heat recycling. The thermoelectric device 200 also can be attached to, for instance, a cooling device to perform cooling.

Alternatively, the graphene with folded configuration having a high electrical conductivity and a low thermal conductivity at the same time can be applied in an electronic device of the related field.

The thermal conductivity κ of the graphene thin film with folded configuration of the disclosure can be calculated by using a method of numerical simulation. The thermal conductivity is mainly calculated through a non-equilibrium molecular dynamics (NEMD) method. The principle of the NEMD method is based on the extraction of energy from a cold zone and transferring an equal amount to a hot zone. Since a heat flux is generated from temperature difference, the NEMD method is in compliance with the laws of conservation of energy and conservation of momentum. A steady state can be obtained at the end, and heat flux, temperature gradient, and the thermal conductivity κ can be calculated in this state. The simulation calculates the thermal conductivity of the graphene thin film with folded configuration at different lengths.

### Embodiment 1

In embodiment 1, a length L and a width W of each of the sheet layers 22 of the graphene thin film 100 are respectively defined as the length L and the width W of a positive area as shown in FIG. 1. In the present embodiment, the width W of each of the sheet layers 22 is fixed at 67.85 angstroms, the number of layers of the sheet layers 22 is 16, a distance d between each of the sheet layers 22 is about 3.37 angstroms, and the total height of the 16 sheet layers is about 54.61 angstroms. Moreover, the thermal conductivity κ of the graphene thin film with folded configuration is calculated by using a method of numerical simulation and changing the length (length L of each of the sheet layers 22) of the positive area. The direction of thermal conduction is the orthogonal direction of the sheet layers 22, that is, the direction of heat flux is the direction perpendicular to the sheet layers 22. The simulation results are as shown in Table 1. Then, the thermal conductivity of the macroscopic length is determined according to a Scaling law, as shown in Table 2.

TABLE 1

| | Length of positive area | | |
|---|---|---|---|
| | (angstroms) | | |
| | 50 | 60 | 100 |
| Coefficient of thermal conductivity (W/m · K) | 7.45 | 9.5 | 9.8 |

TABLE 2

| | Embodiment | |
|---|---|---|
| | 1 | 2 |
| Number of layers | 16 | infinite layer |
| Coefficient of thermal conductivity of length of | 14.49 | 72.42 |
| macroscopic dimension (W/m · K) | | |

### Embodiment 2

The thermal conductivity of the graphene with folded configuration at an infinite length of the positive area is simulated according to the parameters of Table 1 and by changing the number of layers of the sheet layers 22 to infinite.

Referring to Table 1, the results of embodiment 1 show that the thermal conductivity increases with increasing length of the positive area (dimension effect). Referring to Table 2, the thermal conductivity of 16 layers of the graphene thin film with folded configuration of embodiment 1 at an infinite length of the positive area is calculated according to a Scaling law to be about 14.49 W/m.K. The thermal conductivity of an infinite layer of the graphene with folded configuration of embodiment 2 at an infinite length of the positive area is about 72.42 W/m.K.

The thermal conductivity of the known graphene with a monolayer of a large area is between about 2000 and about 5000 W/m.K. In comparison, the thermal conductivity (14.49 W/m.K and 72.42 W/m.K) of the graphene with folded configuration of the disclosure are less than that of the known graphene with a monolayer by 2 orders of magnitude, and are, for instance, about 1/156 to about 1/31 times that of the known graphene with a monolayer. As a result, the thermal conductivity is significantly reduced. It can be known from the results that for graphene with folded configuration the thermal conductivity κ can be efficiently reduced.

The measurement of resistances to a monolayer graphene thin film without folded configuration and three layers of graphene thin films with folded configuration is provided as follows. The present experiment obtains the sheet resistances with a method of four-point measurement. The measurement of bulk resistivity is defined as:

$$ρ = \frac{A}{D} \times \frac{V}{I} \qquad formula ( 4 )$$

wherein A is a cross-sectional area at the current input terminal, D is the distance between two points of voltage measurement, V is voltage, and I is current. Since the graphene material is almost a two-dimensional structure, A only represents the length of the current input terminal.

### Embodiment 3

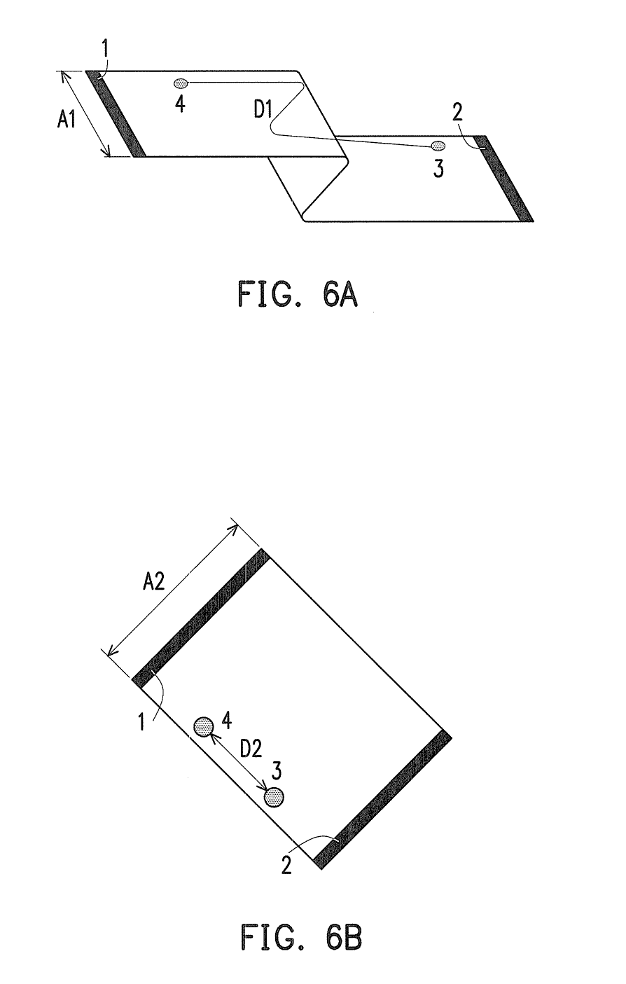

A graphene thin film sample with folded configuration is fabricated. The graphene thin film sample with folded configuration has three layers of the sheet layers 22 as shown in FIG. 6A, and the width W is 11.1 millimeters. To facilitate the measurement, the upper and lower sheet layers are longer, the lengths L of the sheet layers 22 are respectively 10.9 and 8.14 millimeters, and the length L of the middle sheet layer 22 is 5.9 millimeters.

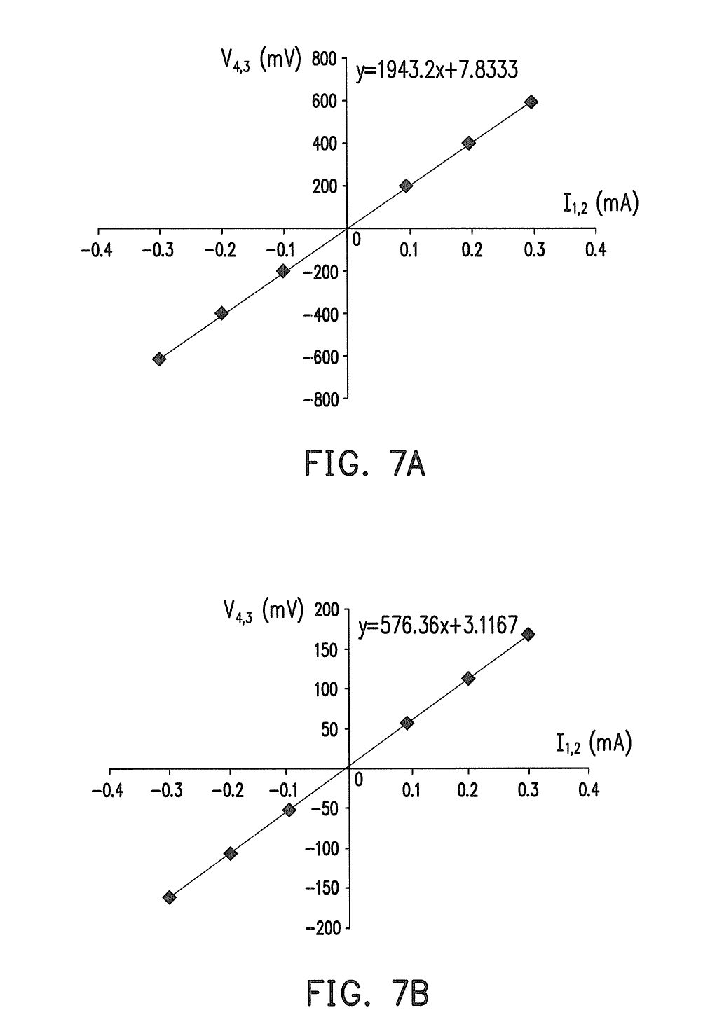

Referring to FIG. 6A, a four-terminal electrode is used in the present embodiment, wherein 1 and 2 are bar electrodes and 3 and 4 are point electrodes. After the path is folded, a distance (D1) between point electrode 4 and point electrode 3 is 14.1 millimeters and a bar length (A1) of bar electrode 1 or bar electrode 2 is 11.1 millimeters. Current is provided to each of bar electrode 1 and bar electrode 2 and the voltage is measured at each of point electrode 4 and point electrode 3. The linear current-voltage (I-V) curve thereof is as shown in FIG. 7A. The resistance is obtained to be about 1943 ohms from the slope of the linear current-voltage curve. The folded distance (D1) between point electrode 4 and point electrode 3 and the length (A1) of the current terminal has a ratio of 1.27:1, and the sheet resistance of the graphene thin film with folded configuration is deduced to be about 1533 ohms after substituting the ratio in formula (4).

### Comparative Embodiment 1

A monolayer graphene thin film sample without folded configuration having a length of 13.20 millimeters and a width of 7.9 millimeters is fabricated. Under the situation that the ratio of a distance (D2) from point electrode 3 to point electrode 4 and a length (A2) of the current terminal is 0.39:1, current is provided to each of bar electrode 1 and bar electrode 2, and the voltage at each of point electrode 4 and point electrode 3 is measured. The linear current-voltage (I-V) curve thereof is as shown in FIG. 7B. The resistance is obtained to be about 576 ohms from the slope of the linear current-voltage curve. The sheet resistance of the monolayer graphene thin film without folded configuration can be determined to be about 1468 ohms with the obtained resistance according to formula (4) above.

The results of embodiment 3 and comparative embodiment 1 show that, the sheet resistance of the graphene thin film with folded configuration is about 1533 ohms, and the resistance of the monolayer graphene thin film without folded configuration is about 1468 ohms. It can be seen that the two resistances are similar. It can be known from the results that the original electrical conductivity of the graphene thin film can be maintained after being folded, that is, the graphene thin film with folded configuration still has the original high electrical conductivity thereof.

Based on the above, the disclosure provides a continuous graphene thin film with folded configuration. Based on the characteristic that the graphene thin film with folded configuration performs thermal conduction in the vertical direction, it can be known from the numerical simulation and the experimental results that the thermal conductivity of the graphene thin film with folded configuration can be significantly reduced without changing the conductive properties thereof in the in-plane direction. As a result, the original high electrical conductivity of the graphene thin film can be maintained. The structure may be applied to manufacture a thermoelectric device having the characteristics of a high electrical conductivity and a low thermal conductivity. A high efficiency thin film thermoelectric device may be obtained through the method of doping treatment to the graphene thin film with folded configuration to improve the thermoelectric power factor.

Although the disclosure has been described with reference to the above embodiments, it will be apparent to one of the ordinary skill in the art that modifications and variations to the described embodiments may be made without departing from the spirit and scope of the disclosure. Accordingly, the scope of the disclosure will be defined by the attached claims not by the above detailed descriptions.

What is claimed is:

1. A graphene thin film with folded configuration, comprising:
a plurality of sheet layers, wherein any two adjacent sheet layers are separated by a distance, each of the sheet layers has a first side and a second side, and the first side and the second side correspond to each other; and
at least one first connecting portion and at least one second connecting portion alternately arranged on both sides of the sheet layers,
wherein one of the at least one first connecting portions connects a first side of an N^{th} sheet layer and a first side of an (N−1)^{th} sheet layer, and one of the at least one second connecting portions connects a second side of the N^{th} sheet layer and a second side of an (N+1)^{th} sheet layer, wherein the N^{th} sheet layer is any one of the sheet layers,
wherein the sheet layers, the at least one first connecting portion, and the at least one second connecting portion form a continuous graphene thin film.

2. The graphene thin film with folded configuration of claim 1, wherein each of the sheet layers, each of the first connecting portions, and each of the second connecting portions respectively comprise a graphene of a monolayer of carbon atoms or multiple layers of carbon atoms.

3. The graphene thin film with folded configuration of claim 2, wherein a thickness of each of the layers of carbon atoms ranges from 0.1 angstroms to 3 nanometers.

4. The graphene thin film with folded configuration of claim 1, wherein the distance is 0.3 nanometers to 10 nanometers.

5. The graphene thin film with folded configuration of claim 1, wherein the sheet layers comprise 2 to 400 layers.

6. The graphene thin film with folded configuration of claim 1, wherein the sheet layers are parallel to one another.

7. The graphene thin film with folded configuration of claim 1, wherein the at least one first connecting portion and the at least one second connecting portion are respectively an arc, a curve, a paraboloid, a cusp, or a vertical plane.

8. A thermoelectric device, comprising:
a lower substrate;
a lower electrode located on the lower substrate;
a graphene thin film with folded configuration located on the lower electrode, wherein the graphene thin film with folded configuration comprises:
a plurality of sheet layers, wherein any two adjacent sheet layers are separated by a distance, each of the sheet layers has a first side and a second side, and the first side and the second side correspond to each other, wherein the sheet layers and a surface of the lower substrate are parallel; and at least one first connecting portion and at least one second connecting portion alternately arranged on both sides of the sheet layers, wherein one of the at least one first connecting portions connects a first side of an N^{th} sheet layer and a first side of an (N−1)^{th} sheet layer, and one of the at least one second connecting portions connects a second side of the N^{th} sheet layer and a second side of an (N+1)^{th} sheet layer, wherein the N^{th} sheet layer is any one of the sheet layers,
wherein the sheet layers, the at least one first connecting portion, and the at least one second connecting portion form a continuous graphene thin film;
an upper electrode located on the graphene thin film with folded configuration; and
an upper substrate located on the upper electrode.

9. The thermoelectric device of claim 8, wherein an orthogonal direction of the sheet layers is a direction of thermal conduction.

10. The thermoelectric device of claim 8, wherein each of the sheet layers, each of the first connecting portions, and each of the second connecting portions respectively comprise a graphene of a monolayer of carbon atoms or multiple layers of carbon atoms.

11. The thermoelectric device of claim 10, wherein a thickness of each of the layers of carbon atoms ranges from 0.1 angstroms to 3 nanometers.

12. The thermoelectric device of claim 8, wherein the distance is 0.3 nanometers to 10 nanometers.

13. The thermoelectric device of claim 8, wherein the sheet layers comprise 2 to 400 layers.

14. The thermoelectric device of claim 8, wherein the sheet layers are parallel to one another.

15. The thermoelectric device of claim 8, wherein the at least one first connecting portion and the at least one second connecting portion are respectively an arc, a curve, a paraboloid, a cusp, or a vertical plane.

16. A fabrication method of a graphene thin film with folded configuration, comprising:
providing a substrate;
forming a graphene layer on the substrate;
forming a protective layer on the graphene layer;
folding the substrate multiple times to form a plurality of connecting portions and a plurality of sheet layers; and
removing the substrate and the protective layer to form a graphene layer with folded configuration.

17. The method of claim 16, wherein a method of forming the graphene layer comprises a vapor deposition method or a mechanical stripping method.

18. The method of claim 16, wherein a method of forming the graphene layer further comprises performing a doping treatment to the graphene layer.

19. The method of claim 18, wherein a method of the doping treatment comprises a plasma method, a heat treatment method, or a solution method.

20. The method of claim 18, wherein a method of the doping treatment comprises implanting nitrogen atoms, hydrogen atoms, oxygen atoms, ammonium atoms, or a combination thereof.

21. The method of claim 16, wherein each of the sheet layers and each of the connecting portions respectively comprise a graphene of a monolayer of carbon atoms or multiple layers of carbon atoms.

22. The method of claim 16, wherein the sheet layers comprise 2 to 400 layers.
